(19) United States
(12) Patent Application Publication
(10) Pub. No.: US 2025/0218678 A1
(43) Pub. Date: Jul. 3, 2025

(54) DIE WITHIN A HOLE IN A SUBSTRATE CORE ATTACHED TO METAL FEATURES OVER THE HOLE

(71) Applicant: Intel Corporation, Santa Clara, CA (US)

(72) Inventors: Hiroki Tanaka, Gilbert, AZ (US); Kristof Darmawikarta, Chandler, AZ (US); Robert May, Chandler, AZ (US); Bai Nie, Chandler, AZ (US); Bohan Shan, Chandler, AZ (US); Gang Duan, Chandler, AZ (US); Srinivas Pietambaram, Chandler, AZ (US)

(73) Assignee: Intel Corporation, Santa Clara, CA (US)

(21) Appl. No.: 18/399,373

(22) Filed: Dec. 28, 2023

(51) Int. Cl. H01G 4/224; H01G 4/228; H01G 4/33; H01L 21/48; H01L 23/00; H01L 23/498; H01L 25/16

(52) U.S. Cl. CPC H01G 4/224; H01L 21/4846; H01L 23/49827; H01L 23/49866; H01L 24/08; H01L 25/16; H01G 4/228; H01G 4/33; H01L 2224/08235

(57) ABSTRACT

An apparatus comprises a substrate core comprising a hole extending from an opening at a first surface of the substrate core to a second surface opposite the first surface. A metal layer is over the first surface. The metal layer comprises a plurality of first metal features over a first portion of the opening. The metal layer also includes a second metal feature extending from a sidewall of the hole and over a second portion of the opening. A die is within the hole and coupled to the first metal features by solder features. The die may comprise a capacitor.

### BACKGROUND

In electronics manufacturing, integrated circuit (IC) packaging is a stage of semiconductor device fabrication in which an IC that has been monolithically fabricated on a chip (or die) is assembled into a “package” that can protect the IC chip from physical damage. The package can also communicatively connect the IC chip to other packaged IC chips and/or a scaled host component, such as a package substrate, or a printed circuit board. Multiple IC chips can be co-assembled, for example, into a multi-die package (MCP).

The package typically includes a substrate that can provide wiring to connect an IC chip on a front side (also referred to as die side) with a host component on an opposite side. In some package architectures, the substrate includes a substrate core with a die within the substrate core coupled with an IC chip on the die side. Manufacturing challenges can result when the thickness of the die and the substrate core differ.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Views referred to as “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure. Further, where considered appropriate, reference labels have been repeated among the figures to indicate corresponding or analogous elements. In the figures:

FIGS. 1A and 1B illustrate a flow diagram of methods for forming a device package structure comprising a substrate core and a die within a hole in the substrate core attached to metal features over the hole by solder features in accordance with some embodiments;

FIGS. 2A through 2M illustrate cross-sectional views of a workpiece evolving to include a device package structure comprising a substrate core and a die within a hole in the substrate core attached to metal features over the hole by solder features as selected operations in the methods illustrated in FIGS. 1A and 1B are performed, in accordance with some embodiments;

FIG. 3 illustrates a cross-sectional view of a die comprising a capacitor, according to one example;

FIGS. 4A through 4C illustrate cross-sectional views of a device package structure evolving to a system including a device package structure comprising a substrate core and a die within a hole in the substrate core attached to metal features over the hole by solder features, in accordance with some embodiments;

FIG. 5 illustrates a mobile computing platform and a data server machine employing one or more of device package structures illustrated in FIG. 4B and/or one or more of the systems illustrated in FIG. 4C, in accordance with some embodiments; and

FIG. 6 is a functional block diagram of an electronic computing device employing one or more of IC device package structures illustrated in FIG. 4B and/or one or more of the systems illustrated in FIG. 4C, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

Integrated circuit (IC) device package structures that include a substrate core and a die within a hole in the substrate core are described herein. In various embodiments, the die is attached to metal features over the hole by solder features. The die can include a capacitor and be prefabricated in a process separate from the process employed to fabricate the device package. The die can be prefabricated from a silicon wafer and a thickness of the die may be limited by the wafer thickness. In various embodiments, the thickness of the die is less than the thickness of the substrate core. When the die is thinner than the substrate core, it can be challenging to align the die in a desired x-y-z position, and to keep the die properly aligned during manufacturing. For example, the die may rotate, shift, or tilt. Further, when an improperly aligned die is encapsulated with a dielectric material, there may be undesirable variations in the thickness of the material. In addition, die misalignment can reduce the yield of successfully fabricated device packages. While a sacrificial panel may be used to stabilize the position of the die within the hole in the substrate, this adds to the time and cost required to manufacture the device package structure.

Advantageously, the IC device package structures described herein permit a die that is thinner than a substrate core to be properly aligned and fixed in a desired x-y-z position without requiring the use of a sacrificial panel. In comparison with some prior methods that do not use a sacrificial panel, an advantage of the embodiments described herein is that rotating, shifting, and tilting of the die may be reduced or substantially eliminated. Another advantage of various embodiments is that variations in the thickness of the dielectric material encapsulating a die may be less than the thickness variations of some known methods. Further, the embodiments described herein may advantageously result in improved manufacturing yields.

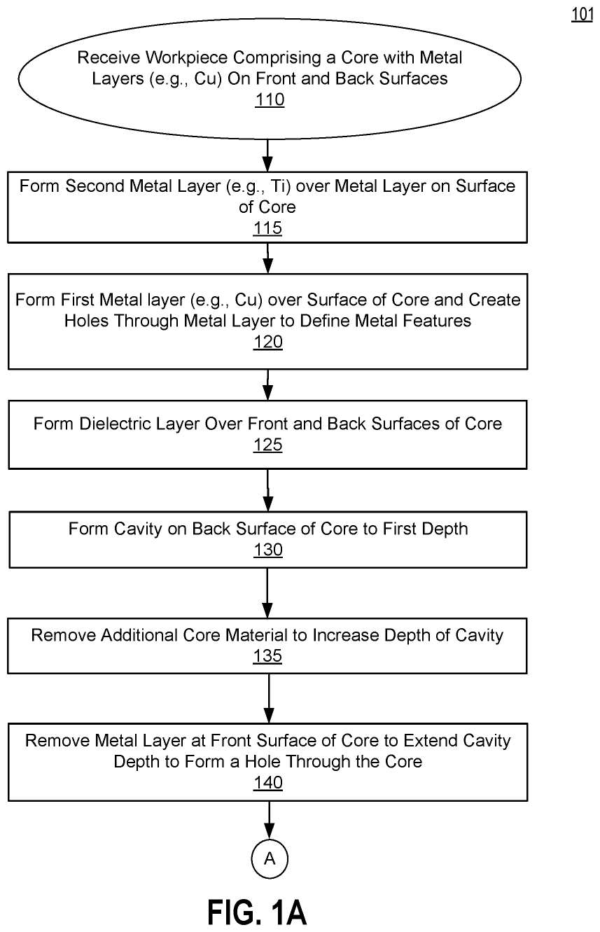

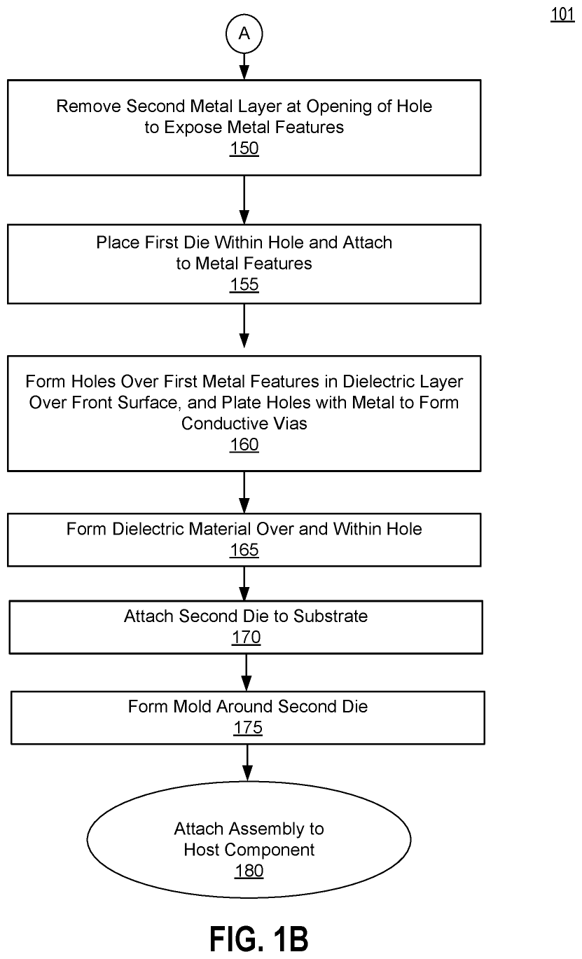

As illustrated in FIGS. 1A and 1B, a variety of fabrication methods may be practiced to form an IC device package assembly having one or more of the features described herein. FIGS. 1A and 1B illustrate a flow diagram of methods for forming an IC device package comprising a substrate core and a die within a hole in the substrate core attached to metal features over the hole by solder features, in accordance with some embodiments. In embodiments, the die has a z-thickness, i.e., a distance in the z-direction, that is less than a z-thickness of the substrate core. The die is electrically coupled to metal features over a surface of the substrate core by solder features. The substrate core may include one or more voltage regulation (VR) circuitry components. In some embodiments, the die within the hole comprises a capacitor. One or more integrated circuit (IC) die may be attached to the substrate and coupled with the die within the hole in the substrate core. The VR circuitry may be for providing power to the one or more die coupled to the substrate.

Methods 101 begin at input block 110 where a workpiece is received. The workpiece may be prepared upstream of methods 101 and may be in a large panel format, a wafer format, or the like. The workpiece may have been previously formed into any shape suitable for a packaging workpiece, such as rectangular in plan view, i.e., in the x-y plane. The workpiece comprises a substrate. The substrate comprises a substrate core and one layer or multiple layers on substrate core. In embodiments, the substrate core may have a metal layer on a first surface, the second surface, or on both the first and second surfaces, e.g., the workpiece may be a copper clad laminate material.

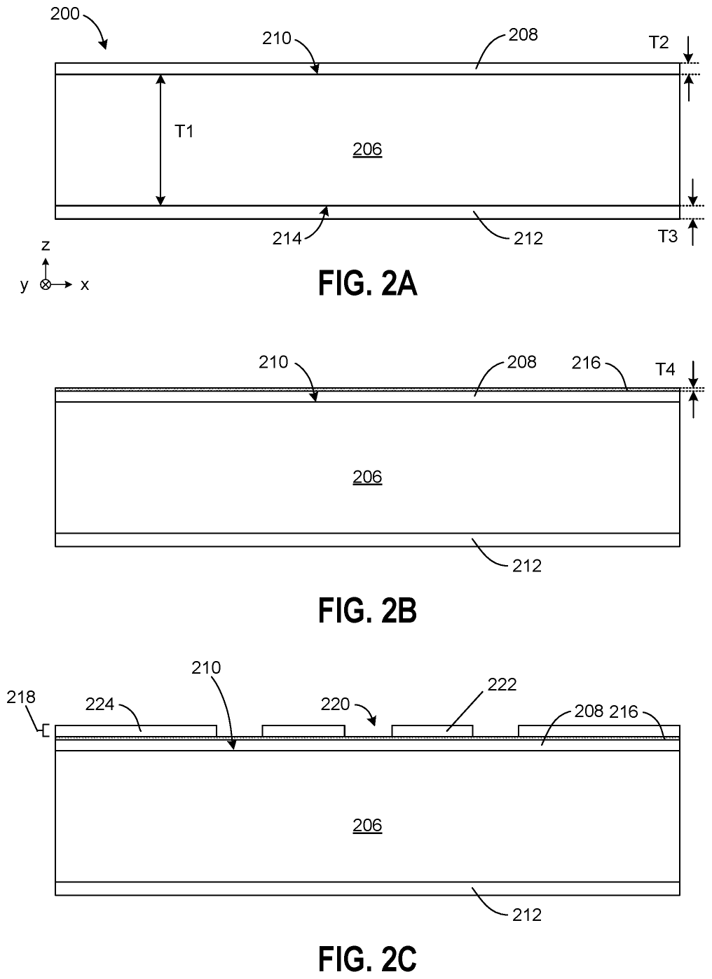

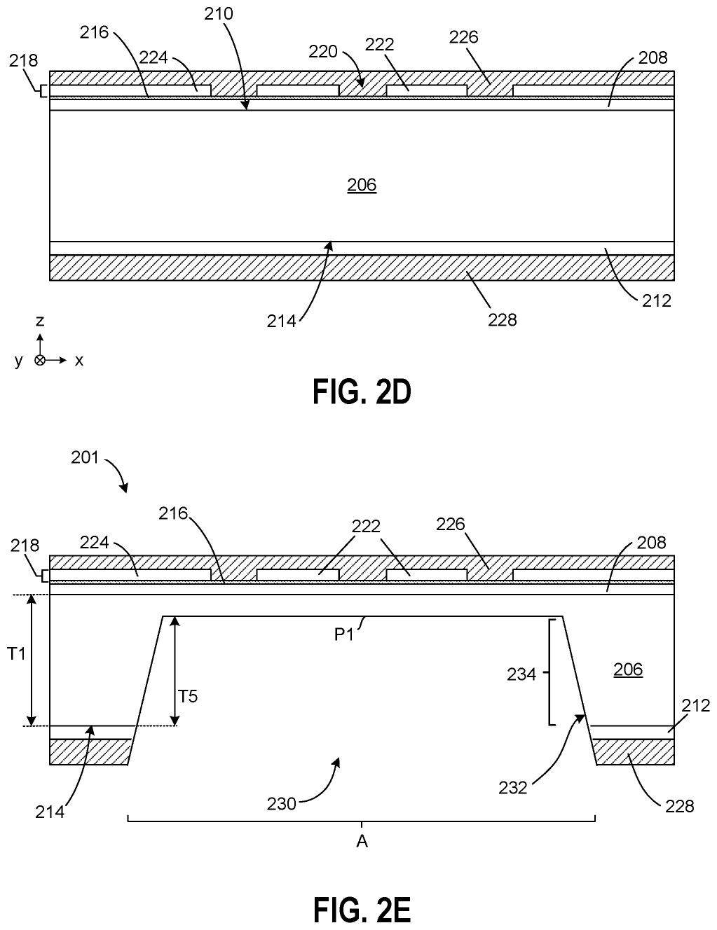

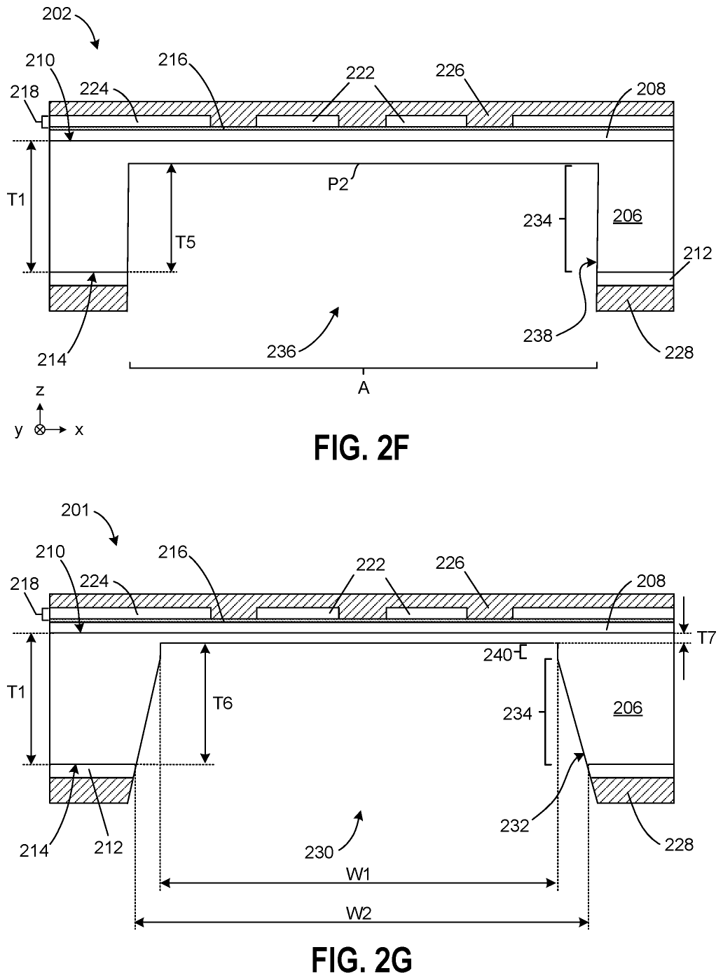

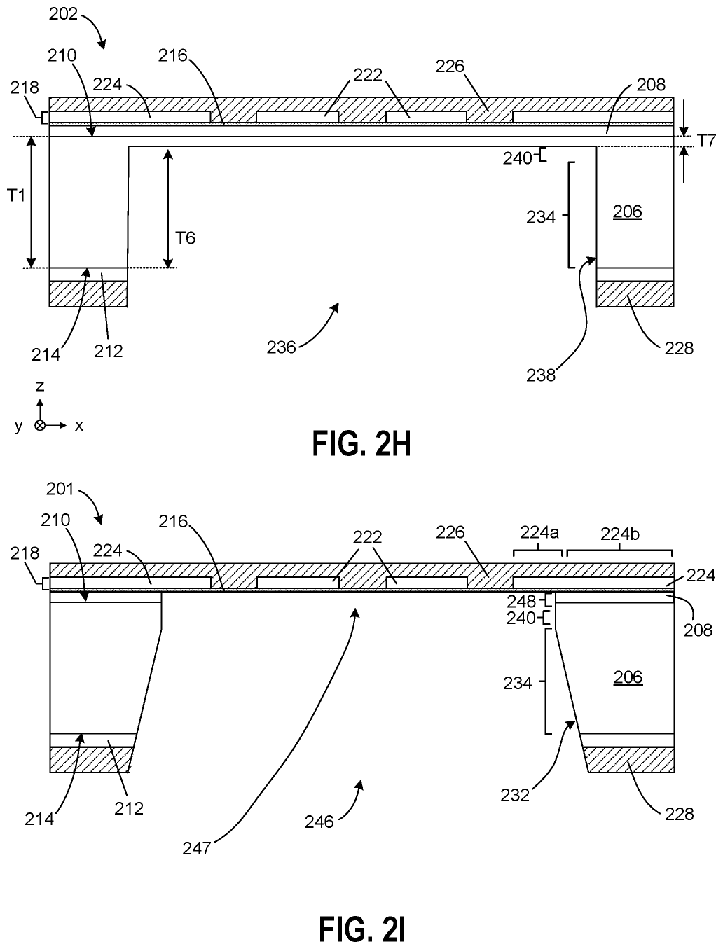

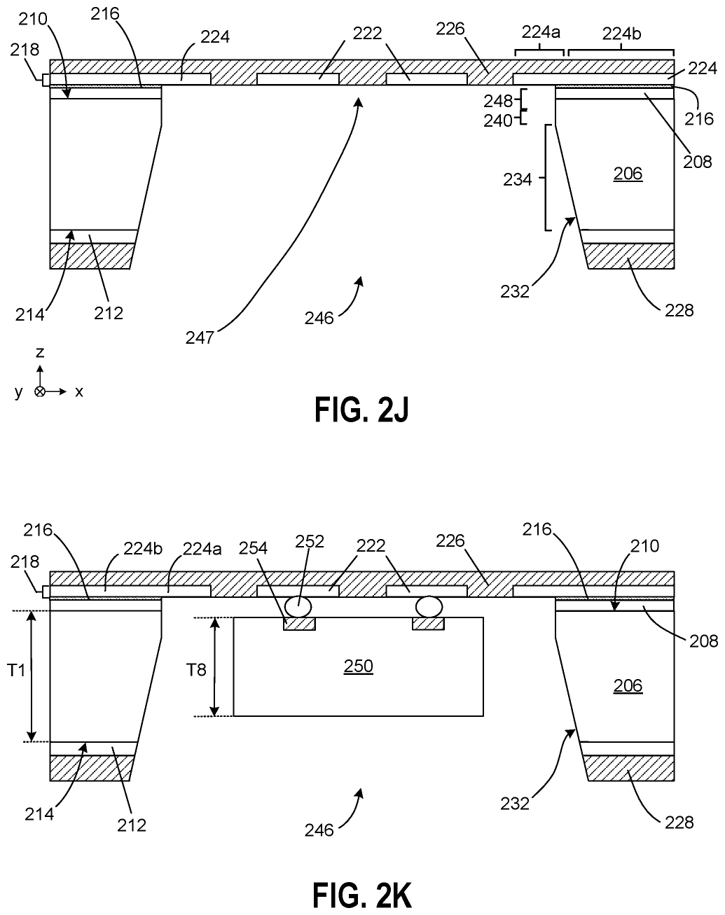

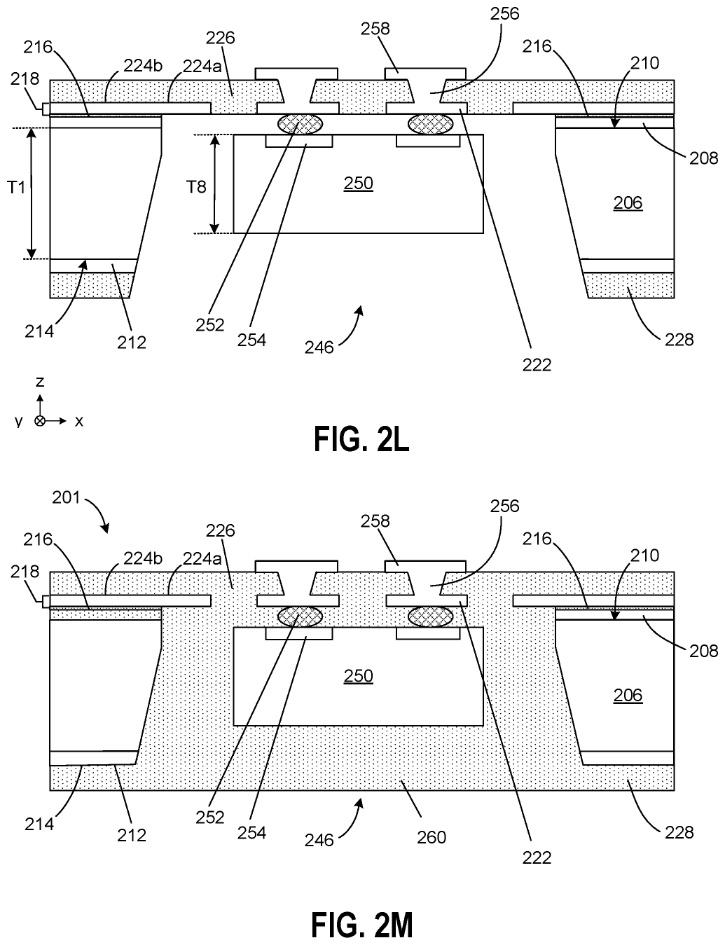

FIG. 2A is a cross-sectional view of an exemplary substrate 200 comprising a substrate core 206. The substrate core 206 comprises a first surface 210 and a back surface 214 opposite the first surface. First surface 210 may be referred to as a “front” surface and back surface 214 may be referred to as a “back” surface. The substrate comprises a “front side” metal layer 208 over the front surface 210, and a “back side” metal layer 212 over back surface 214. Substrate core 206 may include one or more material layers. In various embodiments, the substrate core 206 comprises one or more organic materials, e.g., epoxy. The organic material(s) may include fillers, e.g., glass cloth or fibers. In embodiments, the front side metal layer 216 and back side metal layer 212 are copper or compositions that comprise copper. The compositions of front side metal layer 216 and back side metal layer 212 may be the same or different.

In embodiments, the substrate core 206 may include one or more components of voltage regulation (VR) circuitry. The VR circuitry may be for providing power to one or more die coupled with the substrate in an IC device package assembly. The components may include any suitable circuit component, such as resistors, inductors, capacitors, or transistors. With respect to a capacitor, it may be pre-formed in a separate process from the process described in FIGS. 1A and 1B. Preforming a capacitor is advantageous because forming a capacitor, such as a deep-trench capacitor (DTC) requires a process with a relatively large number of stages. In addition, the capacitor itself, when included within a substrate core, only consumes a relatively small portion of the plan view area of the core. For these reasons, it can be more efficient to preform numerous capacitors in a separate process rather than form one or a few capacitors within a substrate core during an IC device package assembly process. After the capacitors are formed, a wafer containing multiple capacitors can be cut into multiple die, each die comprising a capacitor, and a die can be placed within an opening in the core 206 during one stage of forming the IC device package assembly. However, the z-height of the die containing a capacitor may be limited by the capacitor forming process. When a capacitor is formed this way—in a process different from the process used to form the IC device package assembly—the maximum z-height of the die containing a capacitor may be less than the thickness T1 of substrate core 206.

The thickness T1 of substrate core 206 may be greater than the z-height of a die comprising a capacitor for a variety of reasons. One reason is that the substrate core 206 may include one or more inductors. The z-thickness the substrate core 206 may need to be sufficient to accommodate any inductors within the substrate core.

Substrate core 206 has a thickness T1 that may vary with implementation. In embodiments, thickness T1 is between 200 μm to 2000 μm or greater. Front side metal layer 216 and back side metal layer 212 have respective thicknesses T2 and T3 that may vary with implementation. The thicknesses T2 and T3 may be the same or different. In embodiments, thicknesses T2 and T3 may be in the range of 15 μm to 70 μm.

In some embodiments, the substrate core 206 may comprise a glass that is predominantly silicon and oxygen. In some embodiments, the glass comprises at least 23 percent silicon and at least 26 percent oxygen, by weight (i.e., wt. %). A substrate core 206 comprising glass may further include one or more additives, such as, aluminum, boron, magnesium, calcium, barium, tin, sodium, potassium, strontium, phosphorus, zirconium, lithium, titanium, or zinc. In some embodiments where the glass comprises at least 23 wt. % Si and at least 26 wt. % O, the glass further comprises at least 5 wt. % Al. Additives within the glass may form suboxides (A₂O) monoxides (AO), binary oxides (AO₂), ternary oxides (ABO₃), and mixtures thereof. For example, the glass may comprise AlOₓ (e.g., Al₂O₃), BOx (e.g., B₂O₃), MgOₓ (e.g., MgO), CaOₓ (e.g., CaO), SrOₓ (e.g., SrO), BaOₓ (e.g., BaO), SnOₓ (e.g., SnO₂), NaOₓ (e.g., Na₂O), KOₓ (e.g., K₂O), POₓ (e.g., P₂O₃), ZrOₓ (e.g., ZrO₂), LiOₓ (e.g., Li₂O), TiOₓ (e.g., TiO₂), or ZnOₓ (e.g., ZnO₂). Depending on chemical composition, the glass may therefore be referred to as silica, fused silica, aluminosilicate, borosilicate, or alumino-borosilicate, for example.

In embodiments, substrate core 206 comprising glass is advantageously a bulk material of substantially homogeneous composition in contrast to a composite material that may merely comprise glass fillers and/or fibers. Although a substrate core 206 comprising glass is substantially amorphous in some embodiments, the glass may also have other morphology or microstructure, such as polycrystalline (e.g., nanocrystalline).

In embodiments in which substrate core 206 comprises a glass, one or more material layers may clad either or both of the front surface 210 or back surface 214 of substrate core 206 so that substrate core 206 is a bulk or core layer of a multi-layered substrate. Exemplary cladding materials include inorganic materials such as silicon nitride (SiNₓ) or silicon oxynitride (SiOₓN_{y}). In other embodiments, a silicon layer (polycrystalline or monocrystalline) may clad one or both sides of a substrate core 206 comprising a glass. Organic material layers, such as polymer dielectric materials, may also clad one or more sides of a substrate core 206 comprising glass. Hence, while a substrate core 206 comprising glass is advantageously substantially free of organic materials (e.g., no adhesives, etc.), a workpiece may include organic material within a substrate stack that includes glass.

Returning to FIG. 1A, methods 101 continue at block 115 where a metal layer is formed over a surface of the substrate core. In embodiments, the metal layer is formed over first surface 210 and front side metal layer 216, and may be titanium or a composition comprising titanium. The forming of the metal layer may comprise sputter deposition of a metal. FIG. 2B is a cross-sectional view of the substrate 200 after a metal layer 216 has been formed over a surface of substrate core 206. The metal layer 216 may be referred to as a “second” metal layer. The second metal layer 216 is to protect copper features (described below) from being etched or otherwise damaged by copper etch chemistry introduced in a subsequent processing stage. Second metal layer 216 has a thicknesses T4 that may vary with implementation. In embodiments, thicknesses T4 may be in the range of 25 nm to 500 nm.

Referring to FIG. 1A, methods 101 continue at block 120 where another metal layer is formed over first surface 210 and holes are created in the layer to define metal features. The metal layer formed at block 120 may be referred to as a “first” metal layer. In embodiments, the first metal layer is formed over second metal layer 216. The first metal layer may be formed in various ways. For example, the first metal layer may be formed by a subtractive process in which a metal is deposited on first surface 210, a mask is placed over the metal layer, and locations not blocked by the mask are etched. In another example, first metal layer may be formed by an additive process in which a metal is added to specific areas using selective masking or printing. In some examples, the first metal layer may be formed in a semi-additive process.

FIG. 2C is a cross-sectional view of the substrate 200 after an exemplary first metal layer 218 has been formed. The first metal layer 218 includes a plurality of holes 220 at locations where metal is absent from the layer. The plurality of holes 220 in the first metal layer 218 may define a plurality of first metal features 222 and second metal features 224 in first metal layer 218. The first metal features 222 may be referred to as contacts or pads. The first metal layer 218 may comprise any suitable electrically conductive metal, e.g., copper, aluminum, silver, etc. First metal layer 218 has a thickness that may vary with implementation. In embodiments, the thicknesses of the first metal layer 218 may be 15 μm to 70 μm.

Referring to FIG. 1A, methods 101 continue at block 125 where a dielectric layer is formed over first metal layer 218 and front surface 210. In addition, block 125 may include forming a dielectric layer over back side metal layer 212 and back surface 214. FIG. 2D illustrates a cross-sectional view of the substrate 200 after dielectric layer 226 has been formed over first metal layer 218 at first surface 210, and dielectric layer 228 has been formed over back surface 214. Dielectric layers 226 and 228 may have the same composition, or may have different compositions. Dielectric layers 226 and 228 may comprise any suitable dielectric material (e.g., polymer materials, silicon dioxide (Si02), silicon nitride (Si3N4), etc.) and may be formed by any suitable technique, e.g., by deposition, lamination, plasma-enhanced chemical vapor deposition (PECVD), etc. In some embodiments, a dielectric material may be dielectric/organic materials, resins, epoxies, polymer adhesives, silicones, acrylics, polyimides, cyanate esters, thermoplastics, and/or thermosets. In embodiments, the dielectric layers 226 and 228 may be ABF. In embodiments, the dielectric layers 226 and 228 may be any suitable thicknesses. Dielectric layers 226 and 228 may have the same thickness, or may have different thicknesses.

Referring to FIG. 1A, methods 101 continue at block 130 where a cavity is formed in the core to a first depth at the back surface 214. More specifically, a cavity is formed beginning at back surface 214 of substrate core 206 in an area “A” under first metal features 222 in the first metal layer 218. The cavity extends laterally so that it is also partially under second metal features 224. The cavity may be formed in various ways, e.g., a mechanical cutting tool, such as a drill bit, router, or fly cut tool. The cavity extends through substrate core 206, back side metal layer 212, and dielectric layer 228. It is desired to form the cavity through front side metal layer 208, but the cutting tool may not be controllable with sufficient accuracy to ensure that first metal features 222 are not damaged. As such, the cavity may extend into the substrate core 206 to a first depth T5. The first depth T5 may be about 70 to 95 percent of the thickness T1 substrate core 206. The cavity comprises a sidewall that may be perpendicular to the front or back surfaces, or outward sloping, depending on the type of cutting tool used.

FIG. 2E illustrates a cross-sectional view of a substrate 201 after formation of a cavity 230 in a first example. In the example, cavity 230 includes a sidewall 232 in a first sidewall region 234 proximate back side metal layer 212 and back surface 214. In the example of FIG. 2E, sidewall 232 slopes outward, i.e., away from the center of the cavity 230. As illustrated in FIG. 2E, an opening of cavity 230 at the back surface 214 is larger than an opening at a deepest point “P1” of the cavity 230.

FIG. 2F is a cross-sectional view of a substrate 202 after formation of a cavity 230 according to another example. In the example of FIG. 2F, a sidewall 238 is approximately perpendicular to first surface 210 and/or back surface 214. In the example, an opening of cavity 236 at the back surface 214 may be approximately the same as the x-width of the cavity 236 at the deepest point “P2”. In embodiments, sidewalls 232 and 238 within first sidewall region 234 may have a first average surface roughness of approximately between about 5 μm and about 50 μm, depending on the type of cutting tool used and the material composition. For example, an organic material, which may include glass cloth (protruding fibers), will have a greater roughness than a glass material.

Referring to FIG. 1A, methods 101 continue at block 135 where additional material is removed to increase the depth of cavity to a second depth. The depth of the cavity may be increased in various ways, e.g., laser drilling. FIG. 2G and FIG. 2H illustrate cross-sectional views of substrates 201, 202 after additional material has been removed to increase the depth of cavity 230 and cavity 236, respectively. The depth of cavity 230 and cavity 236 are each increased to a second depth T6. The second depth T6 may be about 95 to 99 percent of substrate core 206 thickness T1. After increasing the depth of the cavity at block 135, a thickness or depth T7 of the remaining substrate core material may be 1 μm to 3 μm. After increasing cavity depth at block 135, sidewalls of the cavity comprise a second sidewall region 240 in addition to first sidewall region 234. The second sidewall region 240 is proximate to front side metal layer 208 and first surface 210. As illustrated in FIG. 2G and FIG. 2H, respectively, the portions of sidewalls 232 and 238 within second sidewall region 240 may be approximately perpendicular to first surface 210 and/or back surface 214. In addition, the portions of sidewalls 232 and 238 within second sidewall region 240 may be approximately perpendicular to first metal layer 218. In embodiments, sidewalls 232 and 238 within second sidewall region 240 may have a second average surface roughness of in a range of about 5 to 10 μm, depending on the material composition.

In embodiments, the second average surface roughness of sidewalls 232, 238 within second sidewall region 240 proximate front surface 210 is less than the first average surface roughness of the sidewalls in first sidewall region 234 proximate back surface 214. The difference in surface roughness in the sidewall regions may be due to the use of the different material removal tools, e.g., cutting with a mechanical tool versus laser tool.

In examples in which sidewall 232 slopes outward (e.g., substrate 201), a surface (which will be referred to as an “opening”) of cavity 230 proximate front side metal layer 208 and first surface 210 comprises a first size, and the opening of cavity 230 proximate backside metal layer 212 and back surface 214 comprises a second size. The first and second sizes may be two-dimensional areas in the x-y plane, or one-dimensional cross-sectional dimensions, e.g., a width in the x- or y-dimension. In one example, an opening of cavity 230 proximate the back surface 214 has a width in the x-dimension of W2, and an opening of cavity 230 proximate front side metal layer 208 and the first surface 210 has a width in the x-dimension of W1. As may be seen in FIG. 2G, W2 is greater than W1. In embodiments, the depth of a cavity in substrate core may be increased (in a subsequent stage) to form a hole through the core. An opening of the hole at front side metal layer 208 or proximate the first surface 210 is a first opening, and opening of the hole at backside metal layer 212 or proximate the back surface 214 is a second opening. The first opening may be of a first size, e.g., W1, the second opening may be of a second size, e.g., W2, and the second size is greater than the first size.

Referring again to FIG. 1A, methods 101 continue at block 140 where a portion of the front side metal layer at the front surface of the substrate core is removed. Operations at block 140 remove the thin layer of core material remaining in cavity 230, which results in cavity 230 becoming a hole through substrate core 206. In addition, operations at block 140 remove a portion of the front side metal layer 208 so that the hole formed at block 130 also extends through front side metal layer 208. The thin layer of core material remaining in cavity 230 and the material in first metal layer over cavity 230 may be removed in any suitable way known in the art. In some embodiments, the remaining core material and front side metal layer 208 are removed using a copper etch process.

FIG. 2I illustrates a cross-sectional view of the substrate 201 after core material in cavity 246 and a portion of the front side metal layer 208 over the cavity have been removed. The operations of methods 101 at block 140 (and thereafter) may be substantially the same whether performed with respect to the example of substrate 201 shown in FIG. 2G or the example substrate 202 shown in FIG. 2H. A primary difference between these examples is the slope of the sidewall. Figures showing subsequent processing stages of the example substrate 202 depicted in FIG. 2H are omitted so as to not obscure principals and features of the disclosed embodiments.

As illustrated in the example of FIG. 2I, substrate 201 comprises a hole 246 extending from an opening 247 at the first surface 210 of substrate core 206 to second surface 214 opposite the first surface. During the material removal process, e.g., a copper etch process, second metal layer 216 protects first metal features 222 and second metal features 224 from being etched or otherwise damaged by etch chemistry that may be introduced at block 140. As mentioned, the second metal layer 216 may comprise titanium and the first metal layer 218 may comprise copper. In embodiments, the composition of the second metal layer 216 is different than the composition of the first metal layer 218.

The hole 246 includes sidewall 232, which comprises first sidewall region 234, second sidewall region 240, and a third sidewall region 248. The third sidewall region 248 includes the portion of front side metal layer 208 exposed by the material removal operations at block 140. In embodiments, the portion of sidewall 232 within third sidewall region 248 has a third average surface roughness of less than about 1 μm, depending on the material composition. In embodiments, the third average surface roughness of sidewall 232 within third sidewall region 248 proximate second metal layer 216 and first surface 210 is less than the first average surface roughness of the sidewall 232 in first sidewall region 234.

As may be seen in FIG. 2I, a plurality of first metal features 222 are over a first portion of the opening 247, e.g., over the center portion of opening 247 of hole 246. In addition, it may be seen in FIG. 2I, that the while each second metal feature 224 may be a continuous body of metal, a second metal feature part 224a of each second metal feature 224 extends from sidewall 232 of hole 246 over a second portion of the opening 247, e.g., a portion adjacent to sidewall 232. In some embodiments, the second metal feature part 224a of each second metal feature 224 extends over sidewall 232. In addition, each second metal feature 224 is partially not over hole 246 or opening 247. As such, a second metal feature part 224b of each second metal feature 224 extends away from the opening 247. In other words, a second metal feature 224 may be a metal structure comprised of two parts: one that is projected or cantilevered over the opening 247 (second metal feature 224a) and another part that is over the substrate core in a location away from the hole 246 (second metal feature 224b).

Referring to FIG. 1B, methods 101 continue at block 150 where a portion of the second metal layer 216 at the opening 247 of the hole 246 is removed. The second metal layer 216 may be removed in any suitable way known in the art. In some embodiments, the second metal layer 216 may be removed using a titanium etch process. FIG. 2J illustrates a cross-sectional view of the substrate 201 after the second metal layer 216 has been removed at opening 247 of hole 246. Removal of second metal layer 216 exposes first metal features 222 and part of metal features 224, i.e., second metal feature parts 224a. As may be seen in FIG. 2J, second metal layer 216 is between second metal feature parts 224b and substrate core 206. In addition, front side metal layer 208 is between second metal feature parts 224b and substrate core 206. The front side metal layer 208 is also between the second metal layer 216 and the substrate core 206.

Referring to FIG. 1B, methods 101 continue at block 155 where a first die is placed in the hole 246 and attached to first metal features 222. The first die may be placed in any suitable way known in the art, such as with a pick and place tool. The first die may comprise conductive contacts with solder balls on the conductive contacts. Alternatively, solder balls may be placed on first metal features 222 prior to placement within the hole. Operations at block 155 may include heating and cooling operations to form solder bonds between conductive contacts on the first die and first metal features 222. In embodiments, the first die comprises one or more capacitors. The capacitor may be a DTC or another type of capacitor. In some embodiments, the first die may comprise other circuit elements, such as inductors, resistors, or transistors. FIG. 2K illustrates a cross-sectional view of the substrate 201 after a first die 250 has been placed within hole 246 and coupled to first metal features 222 by solder features 252. The first die 250 may have a z-height or thickness T8 that is less than the z-height or thickness T1 of substrate core 206. In some embodiments, the first die may have a maximum thickness T8 of 650 μm. In embodiments, the first die 250 comprises one or more capacitors. The first die 250 comprises conductive contacts 254 that are coupled with the solder features 252.

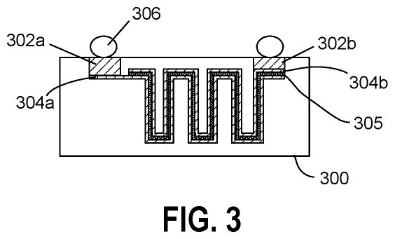

FIG. 3 illustrates a cross-sectional view of a die 300 comprising a capacitor, according to one example. In embodiments, the first die 250 may be the same as or similar to die 300. In an embodiment, die 300 may comprise a deep trench capacitor (DTC). The example die 300 includes conductive contacts 302a and 302b. Conductive contact 302a is electrically coupled with metal structure 304a. Conductive contact 302b is electrically coupled with metal structure 304b. Metal structures 304a and 304b are separated by a dielectric 305. Die 300 may include solder features 306 on conductive contacts 302a and 302b.

Referring again to FIG. 1B, methods 101 continue at block 160 where holes are formed over first metal features 222 in the dielectric layer 226, and the holes are filled with metal to form conductive vias. FIG. 2L illustrates a cross-sectional view of the substrate 201 after holes have been formed over first metal features 222 in dielectric layer 226 and filled with a conductive material, e.g., electroplated with copper, to form conductive vias 256. Conductive contacts 258 may be formed on conductive vias 256 at a surface of the dielectric layer 226 opposite first metal features 222. As shown, each conductive via 256 electrically couples a conductive contact 254 of first die 250 with a conducive contact 258.

Referring again to FIG. 1B, methods 101 continue at block 165 where a dielectric material is formed over and within the hole 246. FIG. 2M illustrates a cross-sectional view of the substrate 201 after a dielectric material 260 has been formed over and within hole 246 through the substrate core 206. The composition of dielectric material 260 may comprise any material that may be included in dielectric layers 226 and 228. In some embodiments, dielectric material 260 may comprise the same composition as dielectric layer 226 or 228.

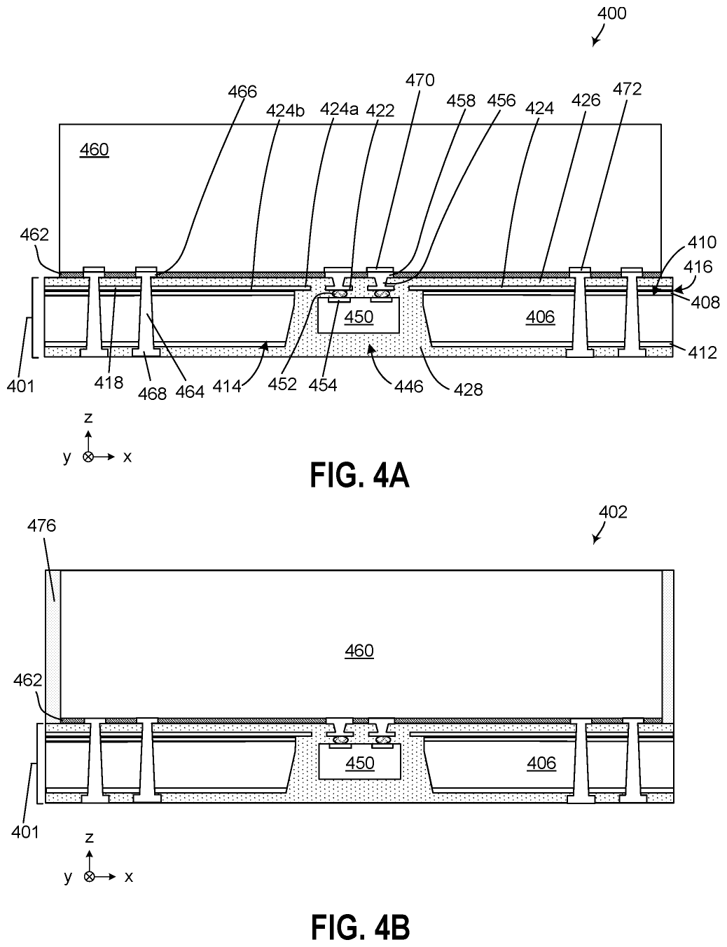

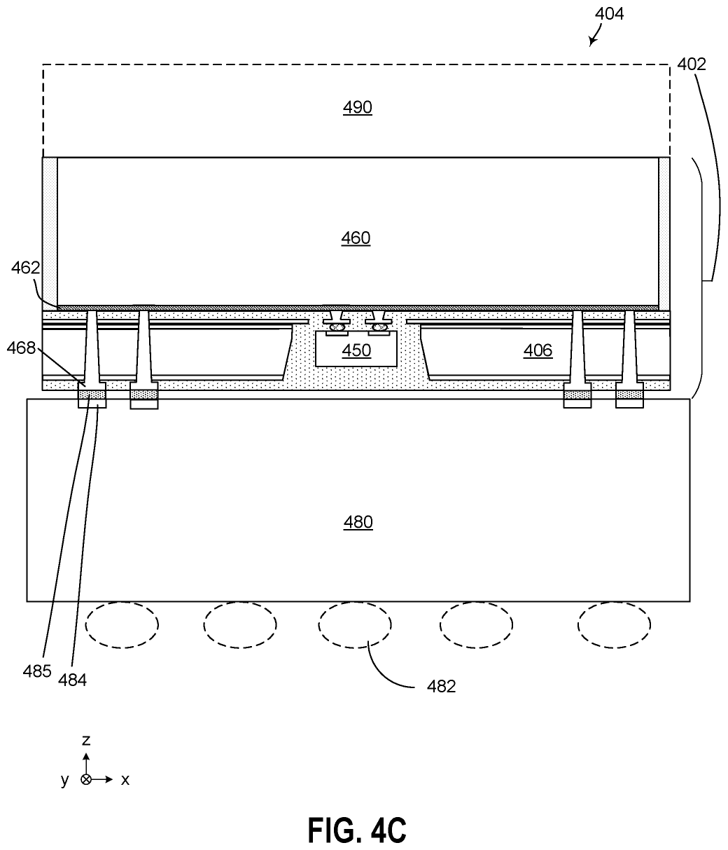

Referring again to FIG. 1B, methods 101 continue at block 170 where one or more second die are attached to a substrate. FIG. 4A illustrates a cross-sectional view of a device package structure 400 that includes a substrate 401 after a second die 460 has been attached to the substrate.

As illustrated in FIG. 4A, the substrate 401 may be the same as or similar to substrate 201. In various embodiments, substrate 401 includes a substrate core 406 with a front side metal layer 408 on a first surface 410 and a backside metal layer 412 on a back surface 414. Front side metal layer 408 and backside metal layer 412 may be the same as or similar to front side metal layer 208 and backside metal layer 212, respectively. The substrate core 406 includes a first metal layer 418 and a second metal layer 416, which may be the same as or similar to first metal layer 218 and second metal layer 216, respectively. The first metal layer 418 includes first metal features 422 and second metal features 424, which may be the same as or similar to first metal features 222 and second metal features 224, respectively. Each second metal feature 424 includes a second metal feature part 424a and a second metal feature part 424b, which may be the same as or similar to second metal feature part 224a and a second metal feature part 224b, respectively. The substrate 401 includes dielectric layers 426 and 428, which may be the same as or similar to dielectric layers 226 and 228, respectively. A first die 450 is within a hole 446 in substrate core 406. First die 450 may be the same as or similar to first die 250. Hole 446 may be the same as or similar to hole 246. The first die 450 includes conductive contacts 454, which are coupled with first metal features 422 by solder features 452. The substrate 401 includes conductive via 456 in dielectric layer 426, which may be the same as or similar to conductive vias 256. The conductive vias 456 are coupled with conductive contacts 458 at a side, e.g., front side, of the substrate 401 and the first metal features 422. The substrate 401 may also include conductive vias 464 that are coupled with conductive contacts 464 at one side of the substrate and conductive contacts 468 at an opposite side of the substrate. In one example, conductive contacts 464 are at a front side of the substrate 401 (proximate front side 410) and conductive contacts 464 are at a back side of the substrate (proximate back side 414).

As illustrated in FIG. 4A, second die 460 may be mechanically coupled to substrate 401 by an adhesive layer 462, which is between a side of substrate 401 having conductive contacts 458, e.g., the front side, and a side of second die 460 proximate substrate 401. The adhesive layer 462 may comprise any suitable adhesive, such as acrylic or epoxy resins.

In embodiments, second die 460 includes conductive contacts 470 and conductive contacts 472 at a side of the second die 460 proximate substrate 401. Conductive contacts 470 are coupled with conductive contacts 458, and conductive contacts 472 are coupled with conductive contacts 466. Second die 460 includes conductive pathways (e.g., lines and vias) coupled with conductive contacts 470, 472. The conductive pathways may be coupled to circuitry (not shown) within the second die 460. Second die 460 may also include conductive features in addition to the shown conductive features 470, 472, which may be on a same or different side of the shown conductive features. Second die 460 may include a semiconductor material, e.g., Si. Second die 460 may an “active” component comprising active devices (e.g., transistors), while in other embodiments, the second die may be a “passive” component that does not contain one or more active devices. In some embodiments, second die 460 may comprise circuitry to perform any desired function. For example, second die 460 may comprise a logic circuit, a power management integrated circuit, a transmitter, a receiver, a memory controller, a communications controller, a controller, a processor, an application specific integrated circuit (ASIC), or a memory. Second die 460 may include multiple instances of circuitry to perform any desired functionality, e.g., multiple processor cores.

Referring again to FIG. 1B, methods 101 continue at block 175 where a mold material around is formed around the one or more second die. FIG. 4B illustrates a cross-sectional view of device package structure 400 evolving to a device package structure 402. The device package structure 402 includes the substrate 401 and second die 460 after a mold material 476 that that has been formed over and around second die 460. The mold material 476 may mechanically secure second die 460 to other components in an IC package. The mold material 476 may occupy space along sidewalls of second die 460, extending in the −z direction. The mold material 476 may occupy space over second die 460. Example materials for mold material 476 include any suitable organic material, such as an epoxy material. Mold material may have a low electrical conductivity, and may be a dielectric. Mold material may comprise a cured (e.g., thermoset) resin or polymer comprising an epoxy or silicone. Mold material may also comprise a variety of fillers. Techniques for encasing a die are well known. As one example, heated, molten mold material may be transferred into cavities around and over a die. Any suitable methods in the art may be used to form mold material 476 around over the second die 460.

Referring again to FIG. 1B, methods 101 complete at output 180 where the assembled device package structure is attached to any suitable host component. FIG. 4C illustrates a cross-sectional view of an exemplary system 404 including one device package structure 402 attached to a host component 480 with interconnects 485, in accordance with some embodiments. In exemplary embodiments, interconnects 485 are solder (e.g., SAC) microbumps although other interconnect features are also possible. In some embodiments, host component 480 is predominantly silicon. Host component 480 may also comprise one or more alternative materials known to be suitable as interposers or package substrates (e.g., an epoxy preform, cored or coreless laminate board, etc.). Host component 480 may also include a printed circuit board (PCB). Host component 480 may include one or more metallized redistribution levels (not depicted) embedded within a dielectric material. Host component 480 may also include one or more IC die embedded therein. Host component 480 may include conductive contacts 484. The conductive contacts 484 may be coupled with contact conductive contacts 468 by interconnects 485.

Host component 480 may include interconnects 482 illustrated in dashed line. Interconnects 482 may comprise any solder (ball, bump, etc.) suitable for a given host board architecture (e.g., surface mount FR4, etc.). Also illustrated in dashed line, one or more heat spreaders and/or heat sinks 490 may be further coupled to device package structure 402, which may be advantageous, for example, where die 460 comprises one or more CPU cores or other circuitry of similar power density.

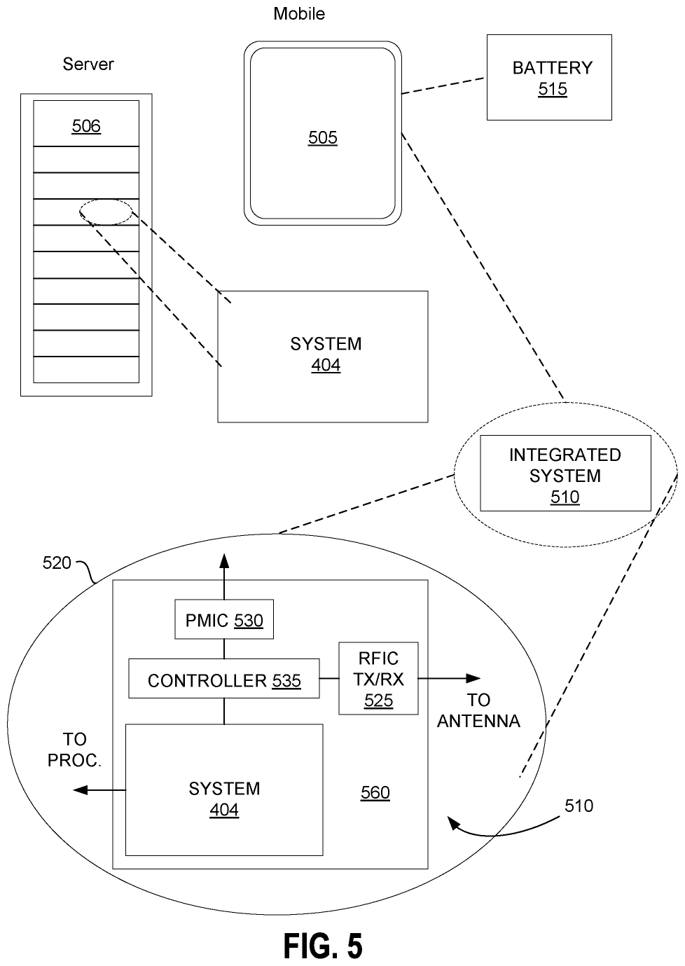

FIG. 5 illustrates a mobile computing platform and a data server machine employing an IC device package a substrate core and a die within a hole in the substrate core attached to metal features over the hole by solder features, for example as described elsewhere herein. Server machine 506 may be any commercial server, for example including any number of high-performance computing platforms disposed within a rack and networked together for electronic data processing, which in the exemplary embodiment includes system 404, for example as described elsewhere herein. The mobile computing platform 505 may be any portable device configured for each of electronic data display, electronic data processing, wireless electronic data transmission, or the like. For example, the mobile computing platform 505 may be any of a tablet, a smart phone, laptop computer, etc., and may include a display screen (e.g., a capacitive, inductive, resistive, or optical touchscreen), a chip-level or package-level integrated system 510, and a battery 515.

Whether disposed within the integrated system 510 illustrated in the expanded view 520, or as a stand-alone package within the server machine 506, the integrated system or server machine includes system 404, for example as described elsewhere herein. System 404 may be further coupled to a host substrate 560, along with, one or more of a power management integrated circuit (PMIC) 530, RF (wireless) integrated circuit (RFIC) 525 including a wideband RF (wireless) transmitter and/or receiver (TX/RX) (e.g., including a digital baseband and an analog front-end module further comprises a power amplifier on a transmit path and a low noise amplifier on a receive path), and a controller 535. PMIC 530 may perform battery power regulation, DC-to-DC conversion, etc., and so has an input coupled to battery 515 and with an output providing a current supply to other functional modules. As further illustrated, in the exemplary embodiment, RFIC 525 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

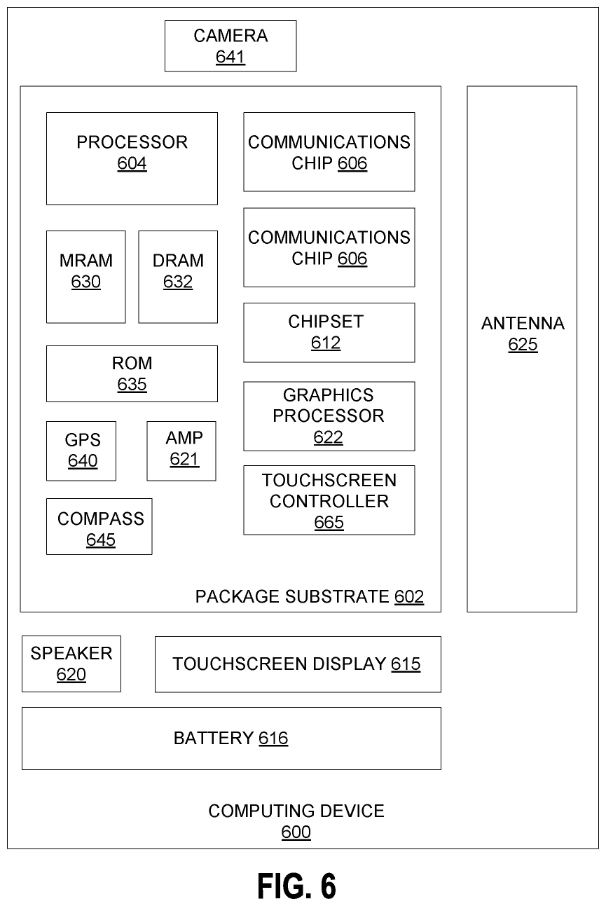

FIG. 6 is a functional block diagram of an electronic computing device 600, in accordance with an embodiment of the present invention. The computing device may include any of the devices or structures discussed elsewhere herein, e.g., device package 402 or system 404. Device 600 further includes a package substrate 602 hosting a number of components, such as, but not limited to, a processor 604 (e.g., an applications processor). Processor 604 may be physically and/or electrically coupled to package substrate 602. In some examples, processor 604 is within system 404, for example, as described elsewhere herein. Processor 604 may be implemented with circuitry in either or both of a host IC chip and a chiplet. In general, the term “processor” or “microprocessor” may refer to any device or portion of a device that processes electronic data from registers and/or memory to transform that electronic data into other electronic data that may be further stored in registers and/or memory.

In various examples, one or more communication chips 606 may also be physically and/or electrically coupled to the package substrate 602. In further implementations, communication chips 606 may be part of processor 604. Depending on its applications, computing device 600 may include other components that may or may not be physically and electrically coupled to package substrate 602. These other components include, but are not limited to, volatile memory (e.g., DRAM 632), non-volatile memory (e.g., ROM 635), flash memory (e.g., NAND or NOR), magnetic memory (MRAM 630), a graphics processor 622, a digital signal processor, a crypto processor, a chipset 612, an antenna 625, touchscreen display 615, touchscreen controller 665, battery 616, audio codec, video codec, power amplifier 621, global positioning system (GPS) device 640, compass 645, accelerometer, gyroscope, speaker 620, camera 641, and mass storage device (such as hard disk drive, solid-state drive (SSD), compact disk (CD), digital versatile disk (DVD), and so forth), or the like. In some exemplary embodiments, one or more of the functional blocks noted above are within device package 402, described elsewhere herein. For example, processor 604 may be implemented within circuitry in a first IC die 250, and an electronic memory (e.g., MRAM 630 or DRAM 632) may be implemented with circuitry in device package 402.

Communication chips 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 606 may implement any of a number of wireless standards or protocols. As discussed, computing device 600 may include a plurality of communication chips 606. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

Example 1: An apparatus, comprising: a substrate core comprising a hole extending from an opening at a first surface of the substrate core to a second surface opposite the first surface; a metal layer over the first surface, the metal layer comprising a plurality of first metal features over a first portion of the opening, and a second metal feature extending from a sidewall of the hole over a second portion of the opening; and a die within the hole coupled to the first metal features by solder features.

Example 2: The apparatus of example 1, wherein the metal layer is a first metal layer and a part of the second metal feature extends away from the opening, further comprising a second metal layer between the part of the second metal feature and the substrate core, wherein a composition of the second metal layer is different than a composition of the first metal layer.

Example 3: The apparatus of example 1 or example 2, wherein the composition of the second metal layer comprises titanium.

Example 4: The apparatus of any of examples 1 through 3, wherein the composition of the first metal layer comprises copper.

Example 5: The apparatus of any of examples 1 through 4, further comprising a third metal layer between the second metal layer and the substrate core, wherein a composition of the third metal layer is different than the composition of the second metal layer.

Example 6: The apparatus of any of examples 1 through 5, wherein the composition of the third metal layer comprises copper.

Example 7: The apparatus of any of examples 1 through 6, wherein the die comprises a capacitor.

Example 8: The apparatus of any of examples 1 through 7, wherein a z-thickness of the die is less than a z-thickness of the hole.

Example 9: The apparatus of any of examples 1 through 8, wherein the sidewall of the hole comprises: a first sidewall region proximate the first surface, the first sidewall region comprising a first average surface roughness; a second sidewall region proximate the second surface, the second sidewall region comprising a second average surface roughness; wherein: the first average surface roughness is less than the second average surface roughness.

Example 10: The apparatus of any of examples 1 through 9, wherein the opening at the first surface is a first opening, further comprising a second opening of the hole at the second surface, wherein: the first opening is of a first size; and the second opening is of a second size greater than the first size.

Example 11: The apparatus of any of examples 1 through 10, wherein the substrate core comprises an organic material.

Example 12: The apparatus of any of examples 1 through 10, wherein the substrate core comprises a glass.

Example 13: The apparatus of any of examples 1 through 11, further comprising a dielectric material within the hole encapsulating the die.

Example 14: The apparatus of any of examples 1 through 10, wherein the substrate core further comprises a dielectric material layer over the metal layer.

Example 15: The apparatus of example 14, further comprising a plurality of conductive vias extending through the dielectric material layer and in direct contact with the first metal features.

Example 15: A system comprising: a package substrate comprising: a substrate core comprising a first surface and a second surface opposite the first surface, and a hole extending from an opening at the first surface to the second surface; a first metal layer over the first surface, the first metal layer comprising a plurality of first metal features over the opening, and a dielectric material between adjacent ones of the first metal features; a second metal layer between the first metal layer and the substrate core, the second metal layer comprising a different composition than the first metal layer; and a die within the hole and coupled to the first metal features by solder features.

Example 16: The system of example 15, wherein the die is a first die, further comprising a second die over the first surface of the substrate core, the second die comprising second metal features coupled with the first metal features.

Example 17: The system of example 15 or example 16, wherein the first die comprises a capacitor.

Example 18: The system of any of examples 15 through 17, wherein the first metal layer further comprises a third metal feature extending over a sidewall of the hole and a portion of the opening.

Example 19: The system of any of examples 15 through 18, wherein the second metal layer comprises titanium.

Example 20: A method for fabricating an IC device structure, the method comprising: receiving a workpiece comprising a core comprising a first surface, a second surface opposite the first surface, and a first metal layer on the first surface; forming a second metal layer over the first metal layer, wherein a composition of the second metal layer is different than a composition of the first metal layer; forming third metal layer over the second metal layer, wherein a composition of the third metal layer is different than a composition of the second metal layer; forming first holes in the third metal layer to define a plurality of metal features in the third metal layer; forming a second hole in the core under the first holes to expose the plurality of metal features; and placing a die within the second hole and attaching the die to the metal features by solder features.

Example 21: The method of example 20, wherein the die comprises a capacitor.

Example 22: The method of example 20 or example 21, wherein the forming a second hole comprises: removing a portion of the first metal layer using a copper etch process; and removing a portion of the second metal layer over the second hole using a titanium etch process.

Example 23: The method of any of examples 20 through 22, wherein the forming a second hole comprises: removing a first portion of the core using a mechanical cutting tool; and removing a second portion of the core using a laser tool.

Example 24: The method of any of examples 20 through 23, further comprising encapsulating the die with a dielectric material.

Example 25: The method of any of examples 20 through 24, further comprising: forming a dielectric material layer over the third metal layer; forming third holes over the metal features in the dielectric material layer; and forming metallization within the third holes to form conductive vias.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should therefore be determined with reference to the appended claims, along with the full scope of equivalents to which such claims are entitled.

What is claimed is:

1. An apparatus, comprising:
a substrate core comprising a hole extending from an opening at a first surface of the substrate core to a second surface opposite the first surface;
a metal layer over the first surface, the metal layer comprising a plurality of first metal features over a first portion of the opening, and a second metal feature extending from a sidewall of the hole over a second portion of the opening; and
a die within the hole coupled to the first metal features by solder features.

2. The apparatus of claim 1, wherein the metal layer is a first metal layer and a part of the second metal feature extends away from the opening, further comprising a second metal layer between the part of the second metal feature and the substrate core, wherein a composition of the second metal layer is different than a composition of the first metal layer.

3. The apparatus of claim 2, wherein the composition of the second metal layer comprises titanium.

4. The apparatus of claim 2, wherein the composition of the first metal layer comprises copper.

5. The apparatus of claim 2, further comprising a third metal layer between the second metal layer and the substrate core, wherein a composition of the third metal layer is different than the composition of the second metal layer.

6. The apparatus of claim 5, wherein the composition of the third metal layer comprises copper.

7. The apparatus of claim 1, wherein the die comprises a capacitor.

8. The apparatus of claim 1, wherein a z-thickness of the die is less than a z-thickness of the hole.

9. The apparatus of claim 1, wherein the sidewall of the hole comprises:
a first sidewall region proximate the first surface, the first sidewall region comprising a first average surface roughness;
a second sidewall region proximate the second surface, the second sidewall region comprising a second average surface roughness; wherein:
the first average surface roughness is less than the second average surface roughness.

10. The apparatus of claim 1, wherein the opening at the first surface is a first opening, further comprising a second opening of the hole at the second surface, wherein:
the first opening is of a first size; and
the second opening is of a second size greater than the first size.

11. The apparatus of claim 1, wherein the substrate core comprises an organic material.

12. The apparatus of claim 1, wherein the substrate core comprises a glass.

13. The apparatus of claim 1, further comprising a dielectric material within the hole encapsulating the die.

14. The apparatus of claim 1, wherein the substrate core further comprises a dielectric material layer over the metal layer, and a plurality of conductive vias extending through the dielectric material layer and in direct contact with the first metal features.

15. A system comprising:
a package substrate comprising:
a substrate core comprising a first surface and a second surface opposite the first surface, and a hole extending from an opening at the first surface to the second surface;
a first metal layer over the first surface, the first metal layer comprising a plurality of first metal features over the opening, and a dielectric material between adjacent ones of the first metal features;
a second metal layer between the first metal layer and the substrate core, the second metal layer comprising a different composition than the first metal layer; and
a die within the hole and coupled to the first metal features by solder features.

16. The system of claim 15, wherein the die is a first die, the first die comprising a capacitor, further comprising a second die over the first surface of the substrate core, the second die comprising second metal features coupled with the first metal features.

17. The system of claim 15, wherein the first metal layer further comprises a third metal feature extending over a sidewall of the hole and a portion of the opening.

18. The system of claim 15, wherein the second metal layer comprises titanium.

19. A method for fabricating an IC device structure, the method comprising:
receiving a workpiece comprising a core comprising a first surface, a second surface opposite the first surface, and a first metal layer on the first surface;
forming a second metal layer over the first metal layer, wherein a composition of the second metal layer is different than a composition of the first metal layer;
forming third metal layer over the second metal layer, wherein a composition of the third metal layer is different than a composition of the second metal layer;
forming first holes in the third metal layer to define a plurality of metal features in the third metal layer;
forming a second hole in the core under the first holes to expose the plurality of metal features; and
placing a die within the second hole and attaching the die to the metal features by solder features.

20. The method of claim 19, wherein the die comprises a capacitor and the second metal layer comprises titanium.
